(19) United States
(12) Patent Application Publication
(10) Pub. No.: US 2015/0303326 A1
(43) Pub. Date: Oct. 22, 2015

(54) INTERCONNECT FOR A THIN FILM PHOTOVOLTAIC SOLAR CELL, AND METHOD OF MAKING THE SAME

(71) Applicant: TSMC SOLAR LTD., Taichung City (TW)

(72) Inventor: Tzu-Huan CHENG, Kaohsiung City (TW)

(73) Assignee: TSMC SOLAR LTD., Taichung City (TW)

(21) Appl. No.: 14/256,049

(22) Filed: Apr. 18, 2014

(51) Int. Cl. H01L 31/0224; H01L 31/18

(52) U.S. Cl. CPC H01L 31/022441; H01L 31/1884; H01L 31/022466

(57) ABSTRACT

A solar cell has a first back contact and a first absorber over the first back contact. The first absorber has a scribe line through it. A first front contact is provided over the first absorber. A first conductive material is provided over a portion of the first front contact. The first conductive material extends through the scribe line and connects to a second back contact of a second solar cell.

### PRIORITY CLAIM AND CROSS-REFERENCE

None.

### BACKGROUND

This disclosure relates to thin film photovoltaic solar cells, and methods of fabricating solar cells. Solar cells are electrical devices for generation of electrical current from sunlight by the photovoltaic (PV) effect. Thin film solar cells have one or more layers of thin films of PV materials deposited on a substrate. The film thickness of the PV materials can be on the order of nanometers or micrometers.

Examples of thin film PV materials used as absorber layers in solar cells include copper indium gallium selenide (CIGS) and cadmium telluride. Absorber layers absorb light for conversion into electrical current. Solar cells include front and back contact layers to assist in light trapping and photo-current extraction and to provide electrical contacts for the solar cell. The front contact typically comprises a transparent conductive oxide (TCO) layer. The TCO layer transmits light through to the absorber layer and conducts current in the plane of the TCO layer.

In some systems, a plurality of solar cells are arranged adjacent to each other, and connected in series. Each solar cell includes an interconnect structure for conveying charge carriers from the front contact of a solar cell to the back contact of the next adjacent solar cell on the same panel. A P1 scribe line separates the back contacts of adjacent first and second solar cells. A P2 scribe line penetrates the absorber of the first solar cell and is filled with the TCO material to connect the front contact of the first solar cell with the rear contact of the second solar cell. A P3 scribe line separates the respective absorbers and front contact layers of the first and second solar cells.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan view of a solar module, in accordance with some embodiments.

FIG. 1B is an enlarged detail of FIG. 1A.

FIG. 2 is a cross sectional view of an interconnect structure of one of the solar cells shown in FIG. 1A, taken across section line 2-2 of FIG. 1A, in accordance with some embodiments.

FIG. 3 is a plan view of another solar module, in accordance with some embodiments.

FIG. 4 is a plan view of another solar module, in accordance with some embodiments.

FIG. 5 is a flow chart of a method of making a solar cell as shown in any of FIG. 1, 3 or 4, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The open circuit voltage (Voc) of a solar module depends on the number of solar cells connected in series within that solar module. Some solar modules include from 100 to 150 solar cells connected in series. Thin film solar modules can provide a high module Voc, such as 60 to 120 V for a solar module having an area of about 1 m², with a short circuit current (Jsc) of 3-4 Amperes But some devices handling the current from the solar module (e.g., inverters) place a constraint on the voltage of the current they accept. For example, some inverters can accept the current generated by 10 solar modules at 3 to 4 Amperes. If a solar cell having a lower Voc can be used, a smaller number of inverters can handle the power from a larger number of solar cells.

Also, the area of the interconnect structures does not contribute to power generation. In some thin film solar modules having 100 to 150 solar cells, the total length of 100 to 150 interconnect structures is 4˜10 mm. Thus the series interconnections between solar cells result in 3˜5% reduction in collection area.

This disclosure describes a solar cell design that allocates a large fraction of total solar cell area to collection, and a small fraction of the total solar cell area to interconnections between solar cells in a solar module, improving collection efficiency. The solar cell design can accommodate a variety of solar cell shapes, sizes and aspect ratios, and is not limited by the width constraints of prior solar cells. The number of solar cells in a solar module can be reduced substantially (for example to a range from 10 to 20 solar cells per solar module). A solar module as described herein having an area of about 1 m² can provide a Voc of 10 to 50 V.

In some embodiments, a P2 scribe line for connecting the front contact of a first solar cell with the back contact of an adjacent second solar cell is formed after the front contact layer. In some embodiments, a portion of the P2 scribe line isolates the absorber, buffer, and front contact layers of the first solar cell from the respective absorber, buffer, and front contact layers of the second solar cell. There is no need for a separate P3 scribe line isolating the respective front contacts, buffer layers and absorbers of adjacent solar cells. The length of the interconnect structure is reduced, due to elimination of the P3 line and a distance between P2 and P3 scribe lines (in prior solar cells having three scribe line). The reduction of the interconnect length can further reduce edge recombination effects, achieving higher solar cell Voc and Jsc.

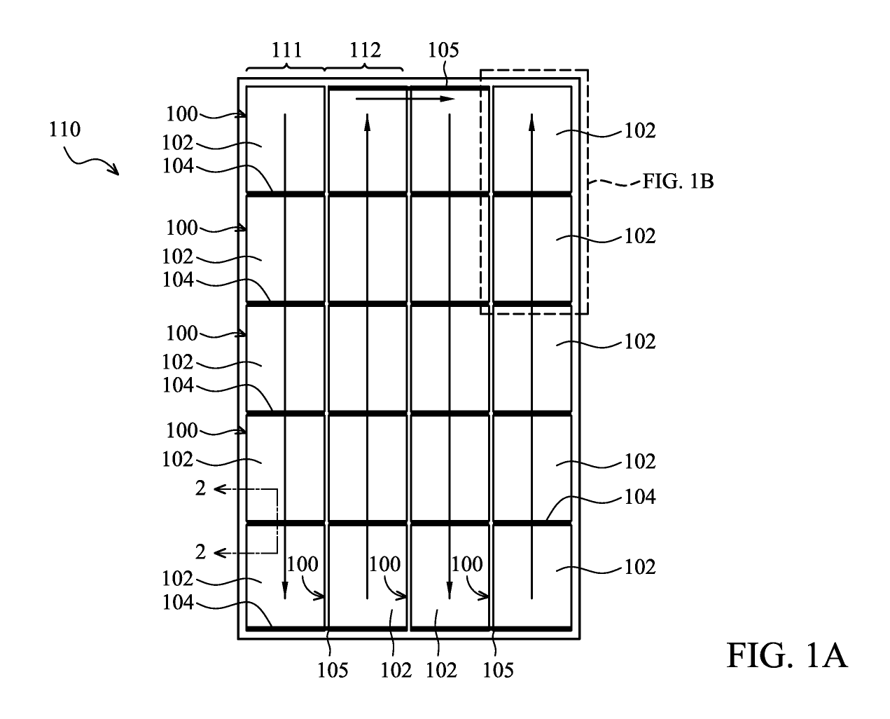

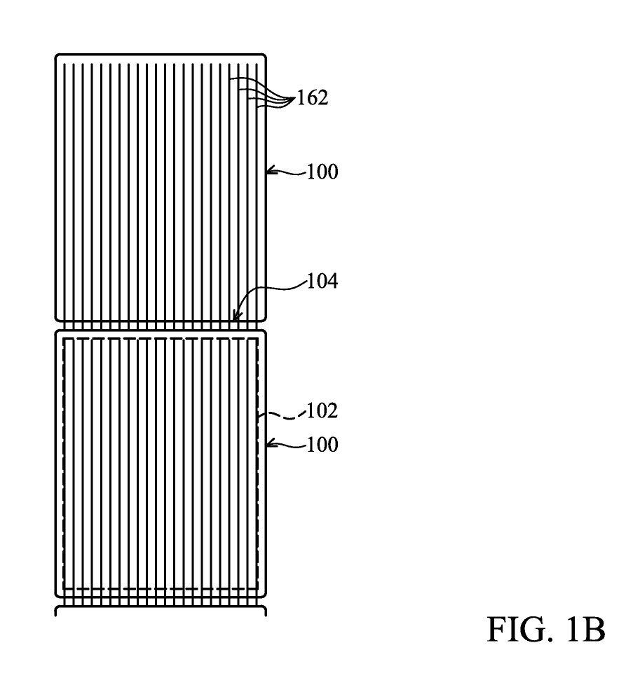

FIG. 1A is a plan view of a solar module 110, in accordance with some embodiments. The solar module 110 has a plurality of solar cells 100. Each solar cell 100 comprises a collection area 102 and an interconnect structure 104. The interconnect structure 104 provides a series connection between two adjacent solar cells 100. In some embodiments, the solar module 110 has a total area of about 1 m², including from 10 to 100 solar cells 100, and a module Voc from 6 to 60 V/module. For example, the solar module 110 of FIG. 1A has 20 solar cells 100.

In some embodiments, the solar cells 100 within the solar module 110 are connected in series in a two dimensional array. For example, in FIG. 1A, arrows show the direction of charge carrier flow among the modules in a serpentine pattern. The current flows down one column 111 of solar cells 100, through the interconnect 105 to column 112, and up the column 112 of solar cells 100. At the end of each column 111, 112, an elongated interconnect structure 105 transmits current in the horizontal direction between adjacent solar cells 100 in two adjacent columns. The solar modules 110 as described herein are not limited to serpentine arrangements, and the solar cells 100 can be connected in series in other arrangements, such as a spiral configuration (not shown), for example.

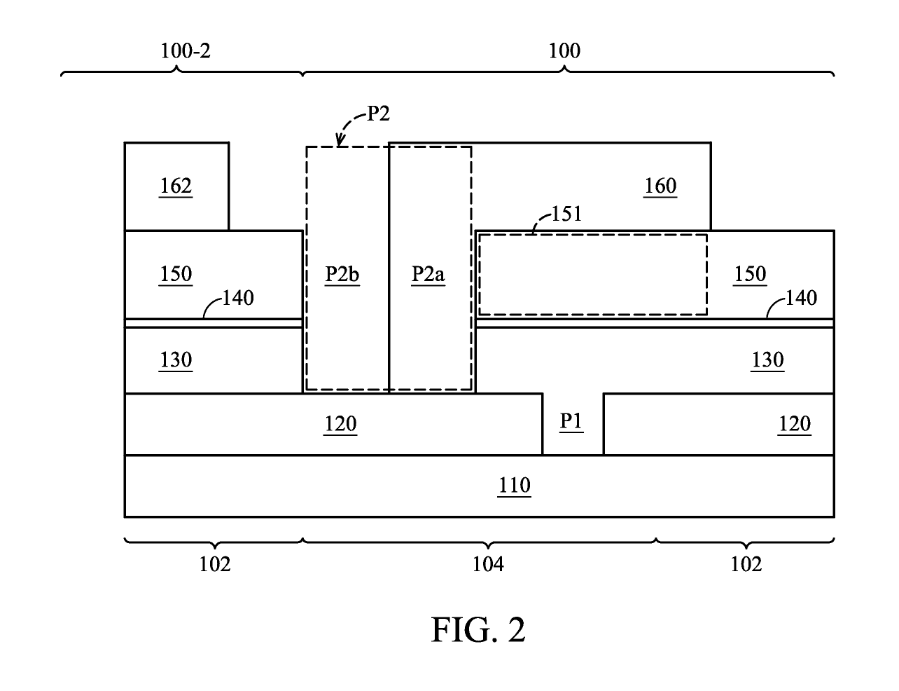

FIG. 2 is a cross-sectional view of a solar cell 100, in accordance with some embodiments. The solar cell 100 includes a solar module substrate 110, a back contact layer 120 on the substrate, an absorber layer 130 over the back contact layer 120, a buffer layer 140 over the absorber layer 130, and a front contact layer 150 comprising a transparent conductive material (such as a transparent conductive oxide, or TCO) over the buffer layer 140.

Substrate 110 can include any suitable solar panel substrate material, such as glass. In some embodiments, substrate 110 includes a glass substrate, such as soda lime glass, or a flexible metal foil or polymer (e.g., a polyimide, polyethylene terephthalate (PET), polyethylene naphthalene (PEN) polymeric hydrocarbons, cellulosic polymers, polycarbonates, polyethers, or others.). Other embodiments include still other substrate materials.

The back contact layer 120 includes any suitable back contact material, such as metal. In some embodiments, back contact layer 120 can include molybdenum (Mo), platinum (Pt), gold (Au), silver (Ag), nickel (Ni), or copper (Cu). Other embodiments include still other back contact materials. In some embodiments, the back contact layer 120 has a thickness in a range from about 50 nm to about 2 μm. In some embodiments, the back contact layer is formed by sputtering.

The absorber layer 130 includes any suitable absorber material, such as a p-type semiconductor. In some embodiments, the absorber layer 130 can include a chalcopyrite-based material comprising, for example, Cu(In,Ga)Se₂ (CIGS), cadmium telluride (CdTe), CuInSe₂ (CIS), CuGaSe₂ (CGS), Cu(In,Ga)Se₂ (CIGS), Cu(In,Ga)(Se,S)₂ (CIGSS), CZTS, CdTe or amorphous silicon. Other embodiments include still other absorber materials. In some embodiments, the absorber layer 130 is from about 0.3 μm to about 8 μm thick. The absorber layer 130 can be applied using a variety of different process. For example, the CIGS precursors can be applied by sputtering. In other embodiments, one or more of the CIGS precursors are applied by evaporation.

In some embodiments, as shown in FIG. 2, the buffer layer 140 includes any suitable buffer material, such as n-type semiconductors. In some embodiments, buffer layer 140 can include CdS, ZnS, zinc selenide (ZnSe), indium(III) sulfide (In₂S₃), indium selenide (In₂Se₃), or Zn₁₋ₓMgₓO, (e.g., ZnO). Other embodiments include still other buffer materials. In some embodiments, the buffer layer 140 is from about 1 nm to about 500 nm thick.

The buffer layer 140 provides a passivation function, and forms a part of the pn junction. In other embodiments, the absorber layer 130 has a high quality surface with few surface defects, so that a separate buffer layer 140 is not included to passivate the absorber layer 130.

In some embodiments, front contact layer 150 includes an annealed transparent conductive oxide (TCO) material. In some embodiments, the TCO layer 150 is highly doped. For example, the charge carrier density of the TCO layer 150 can be from about 1×10¹⁷ cm⁻³ to about 1×10¹⁸ cm⁻³. The TCO material for the annealed TCO layer can include any suitable front contact material, such as metal oxides and metal oxide precursors. In some embodiments, the TCO material can include zinc oxide (ZnO), cadmium oxide (CdO), indium oxide (In₂O₃), tin dioxide (SnO₂), tantalum pentoxide (Ta₂O₅), gallium indium oxide (GaInO₃), (CdSb₂O₃), or indium oxide (ITO). The TCO material can also be doped with a suitable dopant. In some embodiments, ZnO can be doped with any of aluminum (Al), gallium (Ga), boron (B), indium (In), yttrium (Y), scandium (Sc), fluorine (F), vanadium (V), silicon (Si), germanium (Ge), titanium (Ti), zirconium (Zr), hafnium (Hf), magnesium (Mg), arsenic (As), or hydrogen (H). In other embodiments, SnO₂ can be doped with antimony (Sb), F, As, niobium (Nb), or tantalum (Ta). In other embodiments, In2O3 can be doped with tin (Sn), Mo, Ta, tungsten (W), Zr, F, Ge, Nb, Hf, or Mg. In other embodiments, CdO can be doped with In or Sn. In other embodiments, GaInO₃ can be doped with Sn or Ge. In other embodiments, CdSb₂O₃ can be doped with Y. In other embodiments, ITO can be doped with Sn. Other embodiments include still other TCO materials and corresponding dopants. In some embodiments, the front contact layer 150 is from about 5 nm to about 3 μm thick. In some embodiments, the front contact layer 150 is formed by metal organic chemical vapor deposition (MOCVD). In other embodiments, the front contact 150 is formed by sputtering.

It is desirable to have a high solar collection efficiency. Solar cell front contact 150 is made from a TCO material, which is light transparent and conductive. TCO materials are selected for low electrical resistance and high optical transmittance. Reducing the resistance of the TCO layer can reduce parasitic losses in the interconnect structure. But there is a trade-off between resistance and transmittance. Series resistance can be reduced by using a TCO layer that is either thicker or more highly doped, but either of these measures will reduce optical transmittance of the TCO, reducing photon collection.

As shown in FIG. 2, in some embodiments, a first conductive material 160 is provided over a portion 151 of the first front contact 150. The first conductive material 160 extends through a portion P2a of the P2 scribe line and connects to a second back contact 120 of a second solar cell 100-2. Because the highly conductive material 160 reduces optical transmittance in the regions in which it is applied, the highly conductive material 160 has at least one opening above a majority of the collection area 102. For example, as shown in FIG. 1A, the regions 104, 105 having the highly conductive material occupy about 2% of the total area of each solar cell 100 in the solar module 110. The highly conductive material 160 selectively reduces series resistance in the interconnect regions 104, 105, without affecting optical transmittance (or photon collection) outside of the selected regions 104, 105.

In some embodiments, the first conductive layer 160 comprises a highly doped transparent conductive oxide (TCO) material covering a portion 151 of the first front contact 150. In some embodiments, the TCO layer 150 is highly doped. For example, in some embodiments, the charge carrier density of the highly conductive layer 160 can be from about 1×10¹⁷ cm⁻³ to about 1×10¹⁸ cm⁻³. The highly doped TCO material 160 can be selectively applied in the regions 104, 105 shown in FIG. 1A, for example.

In some embodiments, the doping level and doping area of the highly doped TCO material of the first conductive layer 160 can be distributed within the collection area 102 of the solar cell and/or part of the interconnect structure 104. The distribution can be selected based on design parameters of the solar cell 100, such as cell width, TCO resistance, absorber quality (e.g., number of surface defects), and the like.

For example, FIG. 1B shows an enlarged detail of FIG. 1A, including two solar cells 100. In FIG. 1B, additional lines 162 are formed in the highly conductive material layer 160. These lines extend in the direction of current flow, as shown in FIG. 1A. The lines 162 are thin and spaced apart so as to minimize shadowing and reduction in photon collection due to the reduced optical transmittance where the lines 162 are formed. The lines 162 can extend along the entire length of the solar cells 100 as shown in FIG. 1B, or the lines 162 can extend along part of the length of the solar cell. In other embodiments, the lines 162 are omitted. The width of the lines 162 ranges from 2 μm to 2000 μm.

In some embodiments, the highly conductive material 160 is configured in a mesh of connected lines. For example, as shown in FIG. 1B, the parallel lines 162 of highly conductive material extend across the length of each solar cell 100, and are connected to the P2a portion of the highly conductive material 160 in the P2 scribe line.

In other embodiments, the first conductive layer 160 comprises a metal material (e.g., aluminum) covering a portion 151 of the front contact 150 and the P2a portion of the P2 scribe line. In some embodiments, the metal material is selectively applied in the regions 104, 105 shown in FIG. 1A, for example. In some embodiments, the metal material is also included in a plurality of thin parallel lines 162 as shown in FIG. 1B. In some embodiments, the metal material is formed into a mesh.

FIG. 2 also shows the collection area 102 and interconnect structure 104. The drawings are not to scale; the collection area 102 is much longer than the interconnect structure 104. The collection area 102 includes all of the layers 120, 130, 140 and 150, for capturing photons. The interconnect structure 104 includes a P1 scribe line separating the back contacts 120 of adjacent solar cells 100, and filled with absorber material. A P2 scribe line transmits current from the front contact 150 of a solar cell to the back contact 120 of an adjacent solar cell on the left hand side, to connect the solar cells 100 in series. In some embodiments, the P2 scribe line can have a width of from 20 μm to 300 μm, for example.

The P2 scribe line is partially filled with a highly conductive material in a first portion P2a of the P2 scribe line. A second portion P2b of the P2 scribe line is not filled with the conductive material 160. The P2a and P2b portions of the P2 scribe line are adjacent to each other. The second portion P2b of the P2 scribe line separates and isolates the front contact 150, buffer layer 140 and absorber layer 130 of the solar cell 100 from respective front contact 150, buffer layer 140 and absorber layer 130 in the adjacent solar cell 100-2 (only partially shown in FIG. 2) on the left side. There is no need to include a separate P3 scribe line for isolating the front contact 150, buffer layer 140 and absorber layer 130 of the solar cell 100 from like layers in the adjacent second solar cell 100-2. In some embodiments, the first portion P2a of the P2 scribe line is between the P1 scribe line and the second portion P2b of the P2 scribe line. Thus, the single P2 scribe line shown in FIG. 2 performs the functions of the P2 and P3 scribe lines in a solar cell (not shown) having three separate scribe lines in the interconnect region. The interconnect structure shown in FIG. 2 omits a spacing between the P2a and P2b regions, and thus can have a smaller length (and smaller interconnect area) than an interconnect of a solar cell (not shown) having three scribe lines P1, P2 and P3. A length corresponding to the spacing between P2 and P3 scribe lines (not shown) has been eliminated from the structure of FIG. 2. This reduces non-collecting area and increases the fraction of total solar cell area available for photon collection.

Thus, in the configuration of FIG. 2, the width of the interconnect structure 104 can be reduced by the distance between the P2 scribe line and the P3 scribe line in solar cells (not shown) having separate P2 and P3 scribe lines. In some embodiments, the width of the P2a portion of the P2 scribe line is about the same as the width of the P2 scribe line in a solar cell (not shown) having separate P2 and P3 scribe lines. In some embodiments, the width of the P2b portion of the P2 scribe line is about the same as the width of the P3 scribe line in a solar cell (not shown) having separate P2 and P3 scribe lines. In some embodiments, the width of the P2a and/or P2b portions of the P2 scribe line can be less than the P2 or P3 scribe lines of a solar cell (not shown) having both P2 and P3 scribe lines.

In some embodiments, the highly conductive material 160 is applied selectively over only a portion 151 of the front contact 150 and a first portion P2a of the P2 scribe line. The highly conductive material 160 can absorb photons and reduce the number of photons which reach the portion of the absorber 130 underlying the conductive material 160. By only applying the highly conductive material 160 in selected regions (for example, as shown in FIG. 1A), the reduction in photon collection due to the presence of the highly conductive material 160 is minimized.

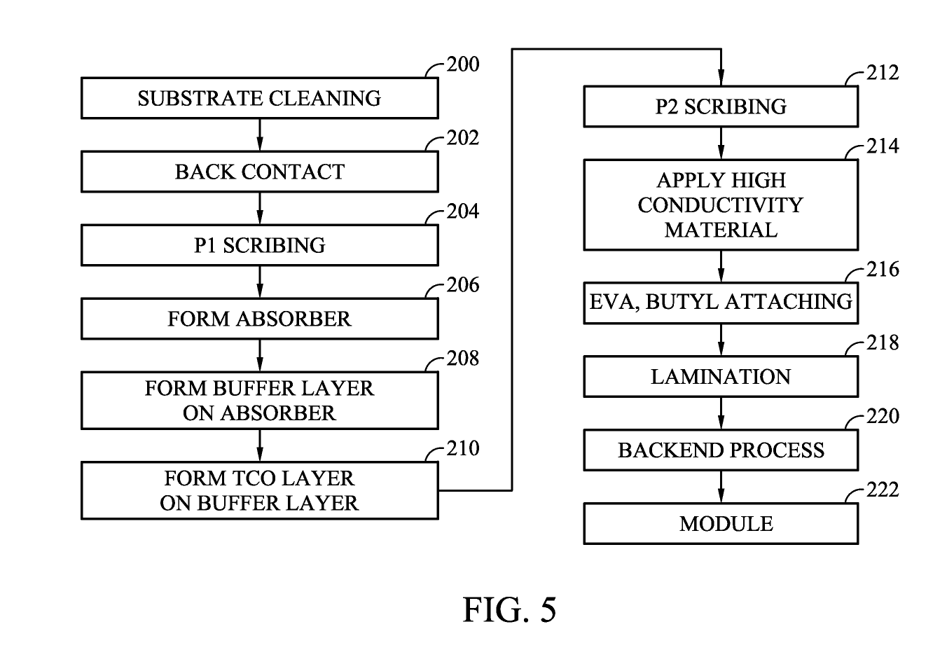

FIG. 5 is a flow chart of a method of making the solar cell 100 of FIG. 1A, in accordance with some embodiments.

At step 200, the substrate is cleaned. In some embodiments, substrate 110 is cleaned by using detergent or chemical in either brushing tool or ultrasonic cleaning tool.

At step 202, back electrode layer 120 is then formed on a substrate 110 by sputtering, atomic layer deposition (ALD), chemical vapor deposition (CVD), or other suitable techniques.

At step 204, the P1 patterned scribe lines are next formed in bottom electrode layer 120 to expose the top surface of substrate 110 as shown. Any suitable scribing method can be used such as, without limitation, mechanical scribing with a stylus or laser scribing.

At step 206, the p-type doped semiconductor light absorber layer 130 is next formed on top of bottom electrode layer 120. The absorber layer 130 material further fills the P1 scribe line and contacts the exposed top surface of substrate 110 to interconnect layer 130 to the substrate. Absorber layer 130 formed of CIGS can be formed by any suitable vacuum or non-vacuum process. Such processes include, without limitation, selenization, sulfurization after selenization (“SAS”), evaporation, sputtering electrodeposition, chemical vapor deposition, or ink spraying or the like.

At step 208, the buffer layer 140 is formed on the absorber 130. The buffer layer 140 can be deposited by chemical deposition (e.g., chemical bath deposition), PVD, ALD, or other suitable techniques.

At step 210, the front contact 150 is formed directly on the buffer layer 140. In some embodiments, the step of forming the front contact 150 can include sputtering a layer of i-ZnO or AZO. In other embodiments, the step of forming the front contact 150 can include metal organic CVD (MOCVD) application of a layer of BZO. The buffer layer deposition step 210 follows the absorber formation step, without any intervening P2 scribing step therebetween.

At step 212, after front contact layer formation, the P2 scribe lines are next cut through the front contact 150, buffer layer 140 and absorber layer 130 to expose the top surface of the bottom electrode 120 within the open P2 scribe line or channel. Any suitable method can be used to cut the P2 scribe line, including without limitation mechanical (e.g. cutting stylus) or laser scribing.

At step 214, the highly conductive material 160 is selectively deposited in the P2a portion of the P2 scribe line and over a small portion of the front contact layer 150. For example, in some embodiments, the highly conductive material 160 covers about 2% of the collection area 102 of the solar cell 100.

In some embodiments, step 214 includes applying a mask covering the second portion P2b of the P2 scribe line. For example, a sacrificial material (not shown) can be applied over the front contact layer, and patterned using a laser, electron bean, or a photolithographic process to form the mask. The sacrificial material is removed from any area on which the highly conductive material 160 is to be formed (i.e., the P2a region and the region 151). The highly conductive material 160 is then applied to fill the P2a portion of the P2 scribe line and cover the small portion 151 of the front contact layer 150 immediately adjacent the P2a portion, but will not be deposited in the regions having the remaining mask material.

In other embodiments, instead of masking portions of the front contact layer 150 which will not be covered by the highly conductive material 160, the highly conductive material 160 is printed on selected portions of the front contact 150 and P2a portion of the P2 scribe line in a grid printing process. The grid printing process begins as a solar panel is placed onto the printing table. A very fine-mesh print screen, mounted within a frame, is placed over the solar panel. The screen blocks off certain areas and leaves other areas open. The paste can go through these open areas. The distance between solar panel and screen is carefully controlled (called the ‘snap-off’ distance). After a measured amount of paste is dispensed onto the screen, a squeegee distributes the paste over the screen to uniformly fill the screen openings. As the squeegee moves across the screen, it pushes the paste through the screen openings and onto the solar panel surface.

In other embodiments, the highly conductive material 160 is deposited over the entire surface of the solar cell 100. Then, a photolithographic process is performed to selectively remove the material 160 from areas except for the P2a portion of the P2 scribe line, and the portion 151 of the front contact 150 immediately adjacent the P2a portion of the scribe line. In some embodiments, anisotropic etching (e.g., reactive ion etch or other dry etching technique) is used to remove the highly conductive material outside of the P2a region and region 151.

At step 216, a combination of ethylene vinyl acetate (EVA) and butyl are applied to seal the solar cell 100. The EVA and butyl encapsulant is applied directly onto the top electrode layer 150 in some embodiments. The EVA/butyl act as a suitable light transmitting encapsulant.

At step 218, heat and pressure are applied to laminate the EVA/butyl film to the front contact 150.

At step 220, additional back end of line processes can be performed. This can include laminating a top cover glass onto solar cell structure to protect the top electrode layer 150.

At step 222, suitable further back end processes can then be completed, which can include forming front conductive grid contacts and one or more anti-reflective coatings (not shown) above top electrode 150. The grid contacts protrude upwards through and beyond the top surface of any anti-reflective coatings for connection to external circuits. The solar cell fabrication process produces a finished and complete thin film solar module 110.

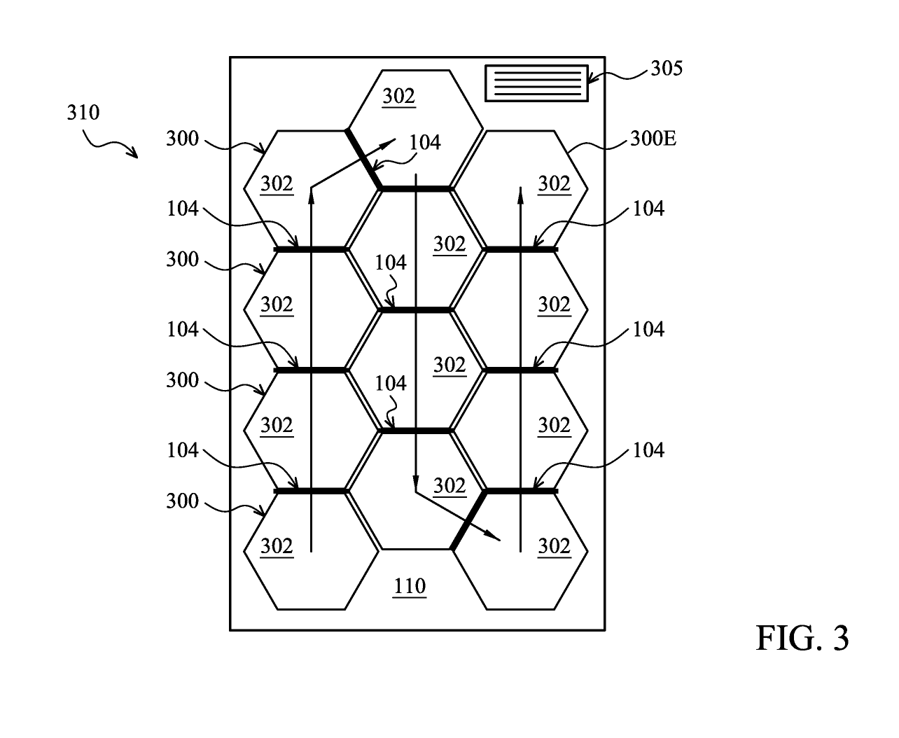

FIG. 3 is a cross sectional view of another solar module 310 according to some embodiments. In FIGS. 1 and 3, like items are indicated by like reference numerals. The solar cells 300 can have a variety of shapes. In some embodiments, as shown in FIG. 3, the individual solar cells 300 in solar module 310 have hexagonally shaped collection areas 302. The solar cells 300 are connected in series in a serpentine arrangement with three columns. The direction of current flow is indicated by arrows. In some embodiments, as shown in FIG. 3, solar cells 300 within each respective column are connected series. The current from the final (right) column flows in parallel into the solar cell 300E at the top right corner of the solar module 310. The substrate 110, back contact 120, absorber layer 130, dielectric layer 145, front contact 150, and the P1 and P2 scribe lines within individual solar cells 300 can be the same as described above with reference to solar cell 100 in FIG. 1A, and except as specifically noted below, their descriptions are not repeated for brevity.

In some embodiments, such as shown in FIG. 3, the arrangement and the shape of the solar cells 300 leaves one or more portions of the solar module substrate 110 uncovered by solar cells 300. The remaining space can be used for indicia 305, such as a logo, trademark, colored pattern, aesthetic pattern, text, advertisement or the like. In some embodiments, the portion of the solar module substrate 110 that is not covered by solar cells 300 can include other types of devices that perform other functions (e.g., a light emitting diode (LED) display).

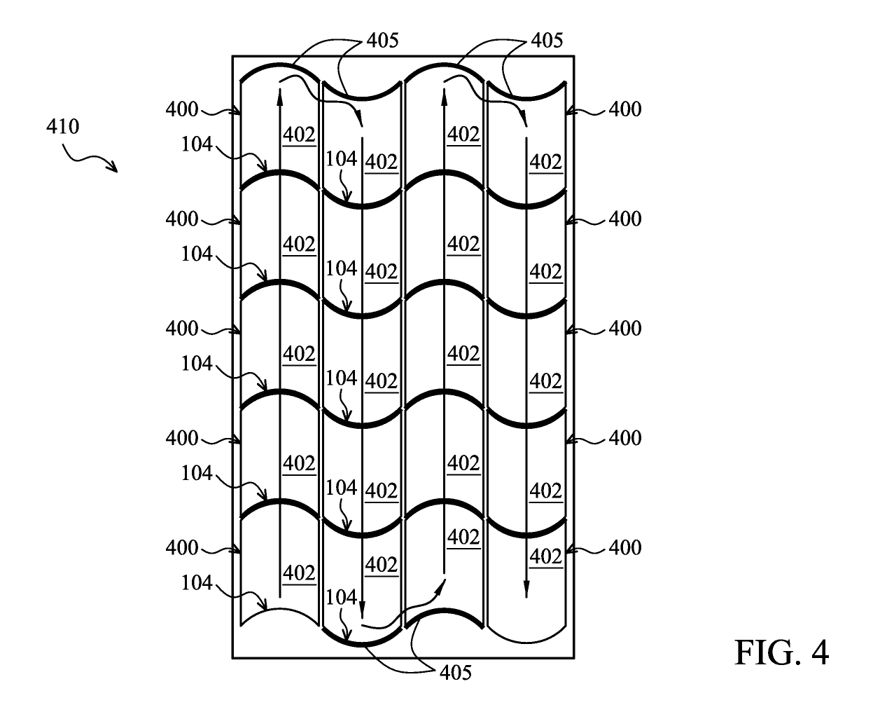

FIG. 4 shows another configuration and arrangement of solar cells 400. The solar cells 400 have collection areas 402 that are not polygons. For example, the solar cells 400 can have curved edges, and the interconnect structures 104 as described above can be formed along the curved edges. The general arrangement of the solar module 410 has solar cells 400 connected in series with the current flow between solar cells 400 in a serpentine arrangement as shown. Within each column of solar cells, the current flows from one end of the column to the other end of the column. The current is transferred between the horizontally adjacent cells at the end of each column by an elongated interconnect 405.

In other embodiments (not shown), the current in each horizontal row of solar cells flows in series, and the vertically adjacent solar cells at the ends of each row are connected by elongated interconnect structures. Thus, in other embodiments (not shown) having curved edges, the interconnect structures can be formed along the straight edges.

The methods described above can be applied for solar cells having p-n or p-i-n junctions, metal-insulator-semiconductor (MIS) structures, multi-junction structures or the like.

In some embodiments, a solar cell in accordance with example 1 above with a 5 nm SiO₂ dielectric layer 145 can improve efficiency, for example, from about 15% to about 16%, which is a percentage increase of 3% to 5%.

Examples are described above, in which the front contact is formed before forming a P2 scribe line, and the P2 scribe line penetrates the front contact, buffer layer and absorber layer. A highly conductive material is applied over a portion of the front contact, and extends through a portion of the P2 scribe line to connect the front contact with a back contact of the next adjacent solar cell, so as to connect the cells in series. This configuration eliminates a separate P3 scribe line that isolates the front contact, buffer layer and absorber layer of adjacent solar cells in other solar cell designs. The length and area of the interconnect structure in each solar cell is reduced, leaving a larger area available for photon collection.

In some embodiments, a solar cell comprises a first back contact and a first absorber over the first back contact. The first absorber has a scribe line therethrough. A first front contact is over the first absorber. A first conductive material is over a portion of the first front contact. The first conductive material extends through the scribe line and connects to a second back contact of a second solar cell.

In some embodiments, a solar cell comprises a first back contact. A first absorber is over the first back contact. The first absorber has a single scribe line extending therethrough. A first front contact is over the first absorber. A first conductive layer is on a portion of the first front contact. The first conductive layer comprises a material that extends through a first portion of the single scribe line and connects to a second back contact of a second solar cell.

In some embodiments, a method of fabricating a solar cell comprises forming a first absorber over a first back contact of the solar cell. A first front contact is formed over the first absorber before forming any scribe line through the first absorber. The scribe line is formed through the first absorber. A conductive material is applied, so as to extend through the scribe line and connect the first front contact to a second back contact of a second solar cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A solar cell comprising:
a first back contact;
a first absorber over the first back contact, the first absorber having a scribe line therethrough;
a first front contact over the first absorber; and
a first conductive material over a portion of the first front contact, the first conductive material extending through the scribe line and connecting to a second back contact of a second solar cell.

2. The solar cell of claim 1, wherein:
the scribe line has a second portion isolating the first absorber and first front contact from a second absorber and second front contact of the second solar cell, respectively.

3. The solar cell of claim 2, wherein the first conductive layer comprises a transparent conductive oxide (TCO) material covering a portion of the first front contact.

4. The solar cell of claim 3, wherein the TCO material is highly doped.

5. The solar cell of claim 2, wherein the first conductive layer comprises a metal material covering a portion of the front contact.

6. The solar cell of claim 1, wherein:
the solar cell has a collection area and an interconnect area; and
the first conductive layer has at least one opening above a majority of the collection area.

7. A solar cell comprising:
a first back contact;
a first absorber over the first back contact, the first absorber having a single scribe line extending therethrough;
a first front contact over the first absorber; and
a first conductive layer on a portion of the first front contact, the first conductive layer comprising a material that extends through a first portion of the single scribe line and connects to a second back contact of a second solar cell.

8. The solar cell of claim 7, wherein the single scribe line has a second portion isolating the first absorber and first front contact from a second absorber and second front contact of the second solar cell, respectively.

9. The solar cell of claim 8, wherein:
the first back contact has a P1 scribe line therethrough, separating the first back contact from a second back contact of the second solar cell; and
the first portion of the single scribe line is between the P1 scribe line and the second portion of the single scribe line.

10. The solar cell of claim 7, wherein the first portion and second portion of the single scribe line are adjacent to each other.

11. The solar cell of claim 7, wherein the first conductive layer comprises a transparent conductive oxide (TCO) mesh covering a portion of the first front contact.

12. The solar cell of claim 7, wherein the first conductive layer comprises a metal mesh covering a portion of the front contact.

13. The solar cell of claim 7, wherein the solar cell has a hexagonal shape.

14. The solar cell of claim 7, further comprising a first buffer between the first absorber and the first front contact, wherein the single scribe line penetrates the first buffer, and the second portion of the single scribe line isolates the first buffer from a second buffer of the second solar cell.

15. A method of fabricating a solar cell, comprising:
forming a first absorber over a first back contact of the solar cell;
forming a first front contact over the first absorber before forming any scribe line through the first absorber;
forming the scribe line through the first absorber; and
applying a conductive material that extends through the scribe line and connects the first front contact to a second back contact of a second solar cell.

16. The method of claim 15, wherein the conductive material is located in a first portion of the scribe line, and the scribe line has a second portion isolating the first absorber and first front contact from a second absorber and second front contact of the second solar cell, respectively.

17. The method of claim 15, further comprising applying a mask over a second portion of the scribe line before applying the conductive material in a first portion of the scribe line.

18. The method of claim 17, wherein the step of applying a conductive material includes applying a metal mesh over a second portion of the front contact layer, the metal mesh including a portion extending through the scribe line.

19. The method of claim 17, wherein the step of applying a conductive material includes providing a doped transparent conductive oxide (TCO) over a second portion of the front contact layer, the doped TCO including a portion extending through the scribe line.

20. The method of claim 15, wherein the method only forms a single scribe line penetrating through the first absorber.
